(19) United States
(12) Patent Application Publication
(10) Pub. No.: US 2012/0270407 A1
(43) Pub. Date: Oct. 25, 2012

(54) SUSCEPTOR FOR SUPPORTING A SEMICONDUCTOR WAFER AND METHOD FOR DEPOSITING A LAYER ON A FRONT SIDE OF A SEMICONDUCTOR WAFER

(75) Inventors: Norbert Werner, Tengling (DE); Christian Hager, Kastl (DE); Reinhard Schauer, Laufen (DE)

(73) Assignee: SILTRONIC AG, Munich (DE)

(21) Appl. No.: 13/418,420

(22) Filed: Mar. 13, 2012

(30) Foreign Application Priority Data
Apr. 19, 2011 (DE) 10 2011 007 682.4

(51) Int. Cl. H01L 21/02; C23C 16/458

(52) U.S. Cl. 438/758; 118/500; 257/E21.002

(57) ABSTRACT

A susceptor for supporting a semiconductor wafer during deposition of a layer on a front side of the semiconductor wafer, the semiconductor wafer having a diameter D and, at its edge, a notch having a depth T, comprising:
a ring-shaped placement area having an internal diameter d for the placement of the semiconductor wafer in the edge region of a rear side of the semiconductor wafer, wherein, with the semiconductor wafer having been placed, the relationship (D−d)/2<T is satisfied; and
a protrusion of the area for the placement of semiconductor wafer in the region of the notch of the semiconductor wafer extending the placement area inward, and which completely underlays the notch of the semiconductor wafer.

### CROSS-REFERENCE TO RELATED APPLICATIONS

This application claims priority to German Patent Application No. DE 10 2011 007 682.4 filed Apr. 19, 2011 which is herein incorporated by reference.

### BACKGROUND OF THE INVENTION

1. Field of the Invention

The invention relates to a susceptor for supporting a semiconductor wafer during deposition of a layer on a front side of the semiconductor wafer, wherein the susceptor has a placement area for the placement of the semiconductor wafer in an edge region of the rear side of the semiconductor wafer. The invention also relates to a method for depositing a layer on a front side of a semiconductor wafer, the susceptor being used in this method.

2. Background Art

Susceptors are known in various embodiments. DE 198 47 101 C1 describes an embodiment wherein the placement area is part of a ring that forms the susceptor. In the embodiment of EP 1 460 679 A1 the susceptor additionally has a base and, as a result, the form of a plate. The placement area is formed by a projection at the edge of the plate. DE 10 2006 055 038 A1 discloses an embodiment wherein the semiconductor wafer lies in the depression of a ring, and the ring lies on a baseplate.

During deposition of a layer on the front side of a semiconductor wafer, endeavors are made, inter alia, to produce a layer having a uniform layer thickness, and to enable the useful area of the layer to extend as close as possible to the edge of the semiconductor wafer. When an attempt is made to implement this endeavor, a problem encountered is that during deposition of the layer on the front side of the semiconductor wafer, process gas also passes into the edge region of the rear side of the semiconductor wafer. This results in uncontrolled material deposition in this region, which adversely affects the flatness of the coated semiconductor wafer. The radial extent of the uncontrolled material deposition is all the greater, the wider the edge region of the semiconductor wafer that is underlaid by the placement area of the susceptor. Since experience shows that the so-called edge exclusion, that is to say the distance from the edge of the semiconductor wafer within which the quality requirements specified by the customer do not have to be satisfied, is becoming ever smaller, it should be expected that the problem causing the uncontrolled material deposition will acquire increasing importance.

A notch is often incorporated in the edge region of the semiconductor wafer, this notch serving for identifying the crystal orientation. A bump composed of deposited material arises around the notch as a result of the uncontrolled material deposition. The bump thus adversely affects the flatness of the semiconductor wafer and disrupts further processing of the semiconductor wafer to form electronic components.

For this reason, JP 2010-034372 A proposes that the radial width of the edge region of the semiconductor wafer that is underlaid by the placement area of the susceptor ought to be as small as possible, but not smaller than the sum of the depth of the notch and the width of a chamfer of the notch. What is disadvantageous about the solution proposed is that, as a result, utilization of the layer deposited on the front side right up to the edge of the semiconductor wafer, owing to uncontrolled material deposition on the rear side of the semiconductor wafer, is only possible to a limited extent.

### SUMMARY OF THE INVENTION

Therefore, the object of the present invention is to propose a susceptor which does not exhibit this disadvantage when it is used. These and other objects are achieved by means of a susceptor for supporting a semiconductor wafer during deposition of a layer on a front side of the semiconductor wafer, wherein the semiconductor wafer has a diameter D and, at its edge, a notch having a depth T, comprising

a ring-shaped placement area having an internal diameter d for the placement of the semiconductor wafer in the edge region of a rear side of the semiconductor wafer, wherein, with the semiconductor wafer having been placed, (D−d)/2<T; and

a protrusion which extends the placement area for the placement of the semiconductor wafer inward in the region of the notch of the semiconductor wafer, and which completely underlays the notch of the placed semiconductor wafer.

The invention also relates to a method for depositing a layer on a front side of a semiconductor wafer, comprising placing the semiconductor wafer on the placement area of the susceptor, and feeding a process gas to the front side of the semiconductor wafer.

### BRIEF DESCRIPTION OF THE DRAWINGS

FIG. 1 shows typical features of a reactor used for depositing a layer on a semiconductor wafer.

FIG. 2 shows one embodiment of a susceptor according to the invention in plan view.

FIG. 3 shows the susceptor of FIG. 2 and, in addition, a semiconductor wafer placed on the susceptor.

FIG. 4 shows the susceptor and the semiconductor wafer of FIG. 3 in cross section.

FIG. 5 shows an enlarged partial excerpt from FIG. 4 in the region of the notch of the semiconductor wafer.

FIGS. 6 and 7 show topographical recordings of the rear sides of a semiconductor wafer produced in accordance with the invention and of a semiconductor wafer produced in accordance with a comparative example.

### DETAILED DESCRIPTION OF THE PREFERRED EMBODIMENT(S)

According to the invention, the susceptor is embodied in such a way that a semiconductor wafer placed on the placement area projects with its edge behind the inner edge of the placement area only to an extent such that a part of the notch of the placed semiconductor wafer would not become located above the placement area if a prong-like protrusion of the placement area were not present. The radial width of the edge region of the semiconductor wafer that is underlaid by the placement area of the susceptor is particularly small, and accordingly so is the radial extent of uncontrolled material deposition on the rear side of the semiconductor wafer which is dependent thereon.

The presence of the protrusion of the placement area in turn ensures that the notch, despite the fact that (D−d)/2<T, is completely underlaid by the placement area. Without the protrusion, the notch, as considered radially from the center to the edge of the semiconductor wafer, would be situated partly in front of and partly behind the inner edge of the placement area. In the region of the notch, the protrusion impedes the access of process gas to the rear side of the semiconductor wafer. A bump composed of material deposited in an uncontrolled manner surrounding the notch on the rear side of the semiconductor wafer, therefore does not develop.

The dimensions of the susceptor preferably satisfies the relationship: 0.2 mm≦(D−d)/2<T. The depth T of the notch denotes the radial distance between the tip of the notch and the edge of the semiconductor wafer, wherein the width of a chamfer of the notch is included in the calculation.

The area of the protrusion is large enough to completely underlay the notch and the chamfer of the notch. It is preferably 20 to 100% larger than the area required for this purpose in order to have leeway if, during the placement of the semiconductor wafer on the susceptor, the correct positioning of that part of the notch which projects inward over the ring-shaped edge of the placement area above the protrusion is not exact. The protrusion is preferably shaped in such a way that it has the contour of part of a triangle, rectangle, square, an ellipse or a circle.

The susceptor preferably consists of silicon carbide or of a material coated therewith, for example graphite, and preferably has the form of a plate, comprising an outer ring, a ring-shaped placement area and a disk-shaped plate base. The ring-shaped placement area can be oriented horizontally or in an inclined fashion and, in the case of the latter, can have a straight or a curved cross section. The susceptor is preferably constructed of but one part or in two parts. In the latter case, the plate base forms one separate constituent part.

The plate base can be gas-impermeable. However, it can also be embodied in a perforated fashion in order to ensure gas transport through holes. However, a plate base having micropores for such gas transport instead of holes is preferred. The micropores can be produced, for example, by fibers and/or particles being compressed to form the plate base and being coated with silicon carbide.

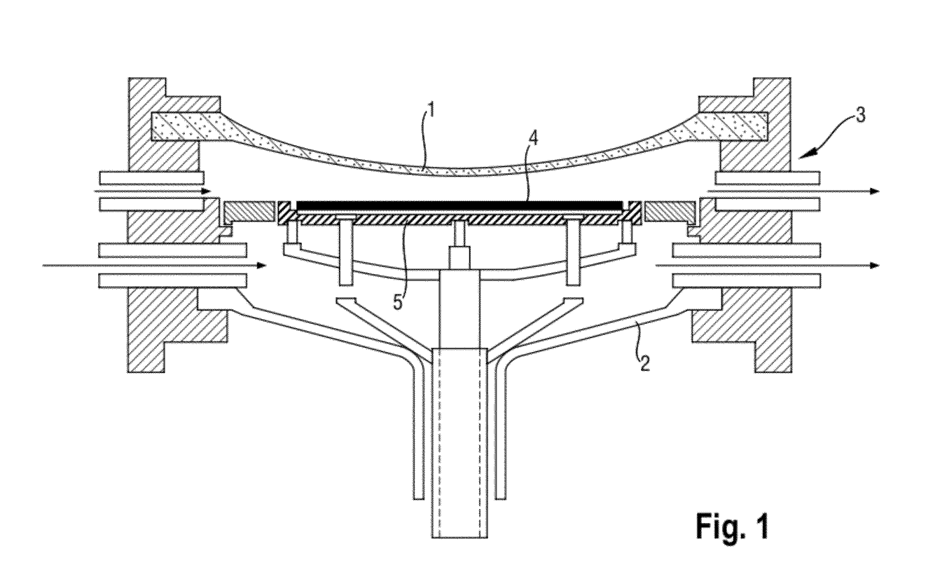

The reactor in accordance with FIG. 1 comprises a chamber having an upper dome 1, a lower dome 2 and a side wall 3. The upper and lower domes 1, 2 are transmissive to thermal radiation emitted by a radiant heating system arranged above and below the chamber. The layer is deposited from the gas phase on the front side of the semiconductor wafer 4 by process gas being directed over the front side of the heated semiconductor wafer and, in the process, reacting with the surface of the exposed front side to form the layer. Front side denotes that side area of the semiconductor wafer on which it is intended to deposit the layer. This usually involves a polished side of the semiconductor wafer. The process gas is fed through a gas inlet in the side wall of the chamber and the waste gas remaining after the reaction is discharged through a gas outlet in the side wall of the chamber. Embodiments of the chamber are known which have a further gas inlet and a further gas outlet. Such embodiments are used, for example, to conduct a purging gas into and out of that volume of the chamber which is present below the semiconductor wafer. With regard to the present invention, it is unimportant whether the further gas inlet and the further gas outlet are present. During the deposition of a layer, the semiconductor wafer is held by a susceptor 5 and rotated together with the susceptor about their center.

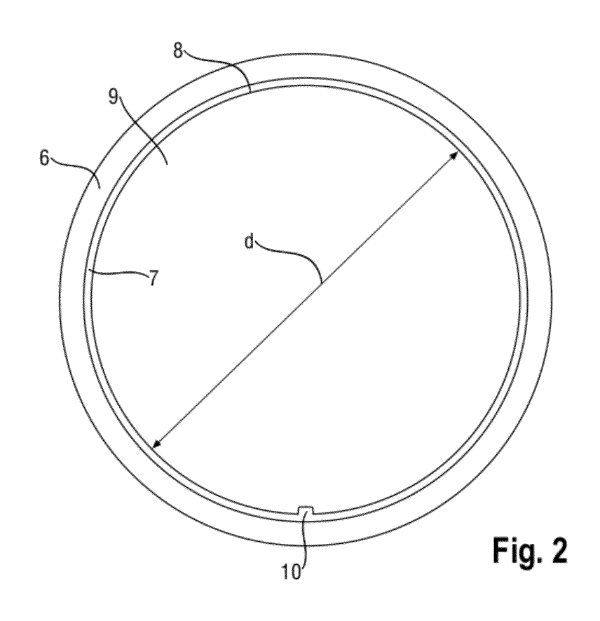

A susceptor of the invention in accordance with FIG. 2 has the form of a plate and comprises an outer ring 6, a ring-shaped placement area 7 with an inner edge 8, and a disk-shaped base 9. The internal diameter D of the placement area corresponds to the diameter of the inner edge 8. The placement area is extended inward by a protrusion 10 at one location.

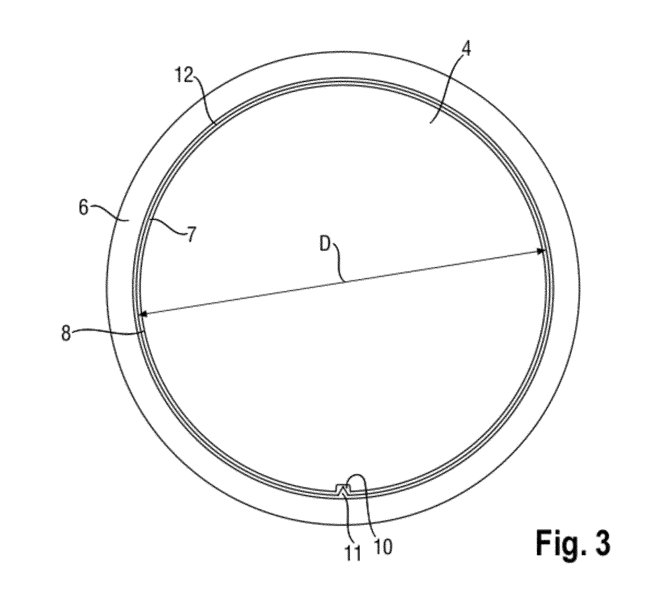

As is illustrated in FIG. 3, a semiconductor wafer 4 placed on the susceptor lies on the susceptor in such a way that the notch 11 becomes located above the protrusion 10. The semiconductor wafer has a diameter D, which is indeed greater than the internal diameter d of the placement area 7. However, the difference is small, such that the outer edge 12 of the semiconductor wafer 4 is situated only slightly behind the inner edge 8 of the placement area 7. It is less than twice the depth of the notch 11.

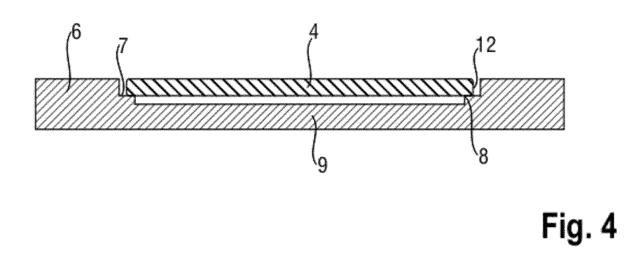

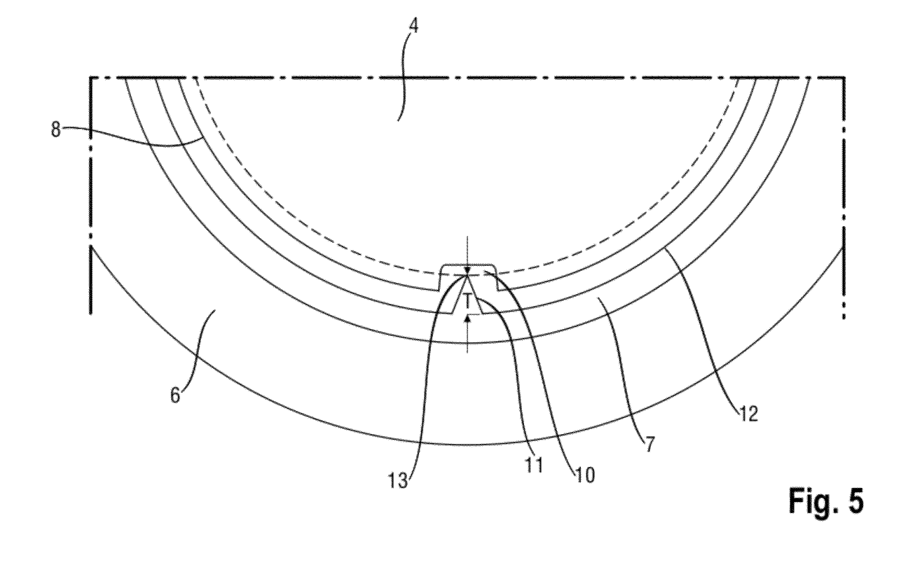

FIG. 4 shows the susceptor and the semiconductor wafer in accordance with FIG. 3 in cross section and FIG. 5 shows an enlarged partial view from FIG. 3.

In accordance with FIG. 5, the notch projects inward partly over the inner edge 8 of the placement area 7. This part of the notch 11 is underlaid by the protrusion 10, and process gas is prevented by the protrusion from passing through the notch to the rear side of the semiconductor wafer. The depth T of the notch denotes the radial distance between the top 13 of the notch and the outer edge 12 of the semiconductor wafer, wherein the width of a chamfer of the notch is included in the calculation.

### EXAMPLE AND COMPARATIVE EXAMPLE

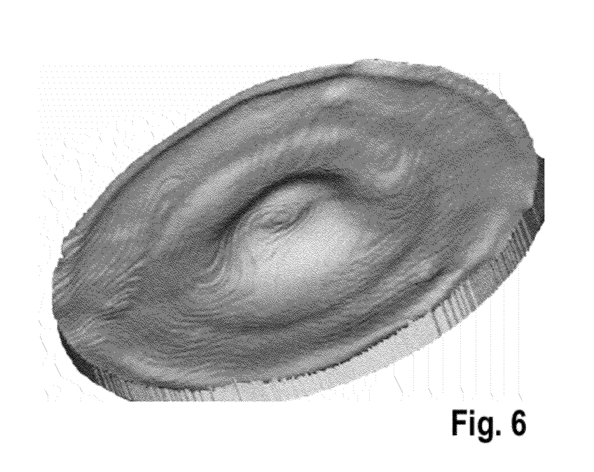

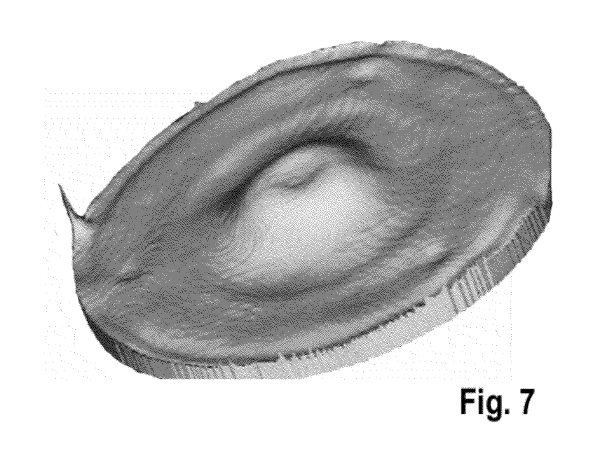

Semiconductor wafers composed of monocrystalline silicon were coated with an epitaxial layer composed of silicon, and the topography of the rear side was subsequently recorded. FIG. 6 shows a recording of a semiconductor wafer in accordance with the invention, which had been coated in an apparatus using a susceptor according to the invention. FIG. 7 shows a recording of a semiconductor wafer in accordance with a comparative example, which had been coated in the same apparatus and under the same conditions, with the exception that the protrusion 10 was absent. In contrast to the semiconductor wafer in accordance with the invention, a grown bump is clearly discernible in the region of the notch in the case of the comparative semiconductor wafer.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A susceptor for supporting a semiconductor wafer during deposition of a layer on a front side of the semiconductor wafer, wherein the semiconductor wafer has a diameter D and, at its edge, a notch having a depth T, comprising:
a ring-shaped placement area having an internal diameter d for the placement of the semiconductor wafer in the edge region of a rear side of the semiconductor wafer, wherein, with the semiconductor wafer having been placed, the relationship (D−d)/2<T is satisfied; and
a protrusion of the placement area for the placement of the semiconductor wafer in the region of the notch of the semiconductor wafer, which extends the placement area inward and completely underlays the notch of the placed semiconductor wafer.

2. The susceptor of claim 1, wherein the area of the protrusion is 20 to 100% larger than necessary to completely underlay the notch and a chamfer of the notch.

3. The susceptor of claim 1, wherein the protrusion is shaped in such a way that it has the contour of part of a triangle, rectangle, square, an ellipse or a circle.

4. A method for depositing a layer on a front side of a semiconductor wafer, comprising
placing the semiconductor wafer on the placement area of a susceptor of claim 1; and feeding a process gas to the front side of the semiconductor wafer.

5. A method for depositing a layer on a front side of a semiconductor wafer, comprising
placing the semiconductor wafer on the placement area of a susceptor of claim 2; and feeding a process gas to the front side of the semiconductor wafer.

6. A method for depositing a layer on a front side of a semiconductor wafer, comprising
placing the semiconductor wafer on the placement area of a susceptor of claim 3; and feeding a process gas to the front side of the semiconductor wafer.
